(19) United States
(12) Patent Application Publication
(10) Pub. No.: US 2019/0019862 A1
(43) Pub. Date: Jan. 17, 2019

(54) COALESCED FIN TO REDUCE FIN BENDING

(71) Applicant: GLOBALFOUNDRIES Inc., Grand Cayman (KY)

(72) Inventors: A K M Zahidur Rahim CHOWDHURY, Beacon, NY (US); Shahrukh Akbar KHAN, Danbury, CT (US); Joseph SHEPARD, JR., Poughkeepsie, NY (US); Mohammad HASANUZZAMAN, Ballston Spa, NY (US); Naved A. SIDDIQUI, Malta, NY (US); Shafaat AHMED, Ballston Lake, NY (US)

(21) Appl. No.: 15/649,294

(22) Filed: Jul. 13, 2017

(51) Int. Cl. H01L 29/06; H01L 29/423; H01L 29/78; H01L 29/66; H01L 21/306; H01L 21/3065; H01L 21/762; H01L 21/324

(52) U.S. Cl. CPC H01L 29/0649; H01L 29/0657; H01L 29/42356; H01L 29/785; H01L 21/324; H01L 21/30625; H01L 21/3065; H01L 21/76224; H01L 29/66795

(57) ABSTRACT

Methods for preventing fin bending in FinFET devices and related devices are provided. Embodiments include forming fins in a substrate; forming a non-conformal sacrificial layer over and between the fins to structurally conjoin the fins or an array of fins for structural integrity; forming a first gap-fill dielectric over the sacrificial layer and fins; recessing the first gap-fill dielectric to expose an upper portion of the fins and sacrificial layer; etching the sacrificial layer to expose the fins; forming a second gap-fill dielectric over the first gap-fill dielectric and over and between the fins; and recessing the second gap-fill dielectric to expose the upper portion of the fins.

### TECHNICAL FIELD

The present disclosure relates to semiconductor processing. In particular, the present disclosure relates to fin field effect transistor (FinFET) fabrication in the 22 nanometer (nm) technology node and beyond.

### BACKGROUND

Structural integrity of FinFET devices, especially in the 7 nm technology node and beyond, is critical for device fabrication and device performance. With existing technology, a steep increase in the shallow trench isolation (STI) aspect ratio is present, thermal budget restrictions exist depending on the doping schemes, and aggressive fin pitches require a void less STI fill at a lower temperature. Conventional approaches include a complex flowable oxide process that provides a seamless STI fill, but asymmetric volume shrinkage and densification that is inherent to the process compromises the structural integrity of the fins resulting in bent or collapsed fins. Moreover, a capillary force resulting in void formation in fin gap regions during flowable chemical vapor deposition (FCVD) can further exacerbate the process.

As illustrated in FIG. 7, a possible cause root cause of fin bending or collapsing is asymmetric stress due to differential volumetric shrinkage. As shown in FIG. 7, a substrate 601 is formed and a plurality of fins 603 are formed from the substrate 601. An STI-fill material 605 is formed at sides of the fins 603 in cross-section view. The effect is more visible with void 607 of STI-fill material 605 in the very last gap. The asymmetric stress is represented by directional arrow 609. The stress-gradient occurs at the upper portion of the STI-fill 605 due to varying densification.

A need therefore exists for methodology enabling elimination of bent or collapsed fins and the related device.

### SUMMARY

The present disclosure provides a solution to the issue of fin bending and collapsing by providing a modified process integration scheme where fins are joined together prior to the gap-fill step so that they are immune to asymmetric strain. Another aspect of the present disclosure includes a decoupled gap-fill step of the narrow fin regions for controlled densification. In another aspect, a second STI deposition fills the narrow region of the fins to just below the very top of the fins.

Additional aspects and other features of the present disclosure will be set forth in the description which follows and in part will be apparent to those having ordinary skill in the art upon examination of the following or may be learned from the practice of the present disclosure. The advantages of the present disclosure may be realized and obtained as particularly pointed out in the appended claims.

According to the present disclosure, some technical effects may be achieved in part by a method including forming fins in a substrate; forming a non-conformal sacrificial layer over and between the fins so as to conjoin the fins or an array of the fins for structural integrity; forming a first gap-fill dielectric over the sacrificial layer and fins; recessing the first gap-fill dielectric to expose an upper portion of the fins and sacrificial layer; etching the sacrificial layer to expose the fins; forming a second gap-fill dielectric over the first gap-fill dielectric and over and between the fins; and recessing the second gap-fill dielectric to expose the upper portion of the fins.

Aspects of the present disclosure include forming a conformal oxide liner over the fins prior to forming the non-conformal sacrificial layer. Other aspects include forming a conformal oxide liner over the fins prior to forming the non-conformal sacrificial layer. Additional aspects include forming the first gap-fill dielectric over the sacrificial layer and fins with chemical vapor deposition (CVD), flowable CVD (FCVD), low-k FCVD SiOC, or spin on dielectric process; and annealing the first gap-fill dielectric. Other aspects include recessing the first gap-fill dielectric by etching; or chemical mechanical polishing (CMP) and reactive ion etching (RIE) deglaze. Further aspects include forming the non-conformal sacrificial layer of silicon nitride or other material that is selective to the etching with respect to the first and second gap-fill dielectrics. Other aspects include forming the second gap-fill dielectric with CVD, FCVD, low-k FCVD SiOC, or spin on dielectric process and annealing the second gap-fill dielectric. Certain aspects include recessing the second gap-fill dielectric by etching; or CMP and RIE deglaze. Additional aspects include etching the non-conformal sacrificial layer to expose the fins, wherein a portion of the sacrificial layer remains at the bottom of the fins adjacent the substrate. Further aspects include forming the non-conformal sacrificial layer, wherein one or more voids are formed between the fins.

Another aspect of the present disclosure is method including forming fins in a substrate; forming a non-conformal sacrificial layer over and between the fins; forming a first gap-fill dielectric over the sacrificial layer and fins; recessing the first gap-fill dielectric to expose an upper portion of the fins and sacrificial layer; etching the sacrificial layer to expose the fins; and forming a second gap-fill dielectric over the first gap-fill dielectric leaving exposed an upper portion of the fins.

Aspects include forming a conformal oxide liner over the fins prior to forming the non-conformal sacrificial layer. Further aspects include forming the first gap-fill dielectric over the sacrificial layer and fins with CVD, FCVD, low-k FCVD SiOC, or spin on dielectric process and annealing the first gap-fill dielectric. Other aspects include recessing the first gap-fill dielectric by etching; or CMP and RIE deglaze. Additional aspects include forming the non-conformal sacrificial layer of silicon nitride or other material that is selective to the etching with respect to the first and second gap-fill dielectrics. Yet another aspect includes forming the second gap-fill dielectric with a controlled CVD, FCVD, low-k FCVD SiOC, or spin on dielectric process (e.g., polysilazane or other organics); and annealing the second gap-fill dielectric.

According to the present disclosure, some technical effects may be achieved in part by a device including fins formed in a substrate; an etched sacrificial layer formed over the substrate and extending to a lower portion of the fins; a first gap-fill dielectric formed over the sacrificial layer extending up sides of the fins exposing an upper portion of the fins; a second gap-fill dielectric formed over the first gap-fill dielectric and between the fins exposing the upper portion of the fins.

Aspects include the etched sacrificial layer including silicon nitride (SiN) or other material that is selective to the etching process with respect to the first and second gap-fill layers. Other aspects include the first gap-fill dielectric including a STI gap fill material. Yet another aspect includes a conformal oxide liner formed over the fins. Additional aspects include comprising a gate formed over the upper portion of the fins.

Additional aspects and technical effects of the present disclosure will become readily apparent to those skilled in the art from the following detailed description wherein embodiments of the present disclosure are described simply by way of illustration of the best mode contemplated to carry out the present disclosure. As will be realized, the present disclosure is capable of other and different embodiments, and its several details are capable of modifications in various obvious respects, all without departing from the present disclosure. Accordingly, the drawings and description are to be regarded as illustrative in nature, and not as restrictive.

### BRIEF DESCRIPTION OF THE DRAWINGS

The present disclosure is illustrated by way of example, and not by way of limitation, in the figures of the accompanying drawing and in which like reference numerals refer to similar elements and in which:

FIGS. 1 through 6 schematically illustrate cross-sectional views of a process flow for producing a FinFET structure without bent or collapsed fins, in accordance with exemplary embodiment; and

FIG. 7 schematically illustrates a cross-sectional view of a STI gap fill void caused by asymmetric stress during conventional processing.

### DETAILED DESCRIPTION

In the following description, for the purposes of explanation, numerous specific details are set forth in order to provide a thorough understanding of exemplary embodiments. It should be apparent, however, that exemplary embodiments may be practiced without these specific details or with an equivalent arrangement. In other instances, well-known structures and devices are shown in block diagram form in order to avoid unnecessarily obscuring exemplary embodiments. In addition, unless otherwise indicated, all numbers expressing quantities, ratios, and numerical properties of ingredients, reaction conditions, and so forth used in the specification and claims are to be understood as being modified in all instances by the term “about.”

The present disclosure addresses and solves the current problem of fin bending or collapsing during FinFET device formation. The present disclosure eliminates fin bending or collapsing during FinFET formation, inter alia, by joining the fins together prior to the gap-fill step so that they are immune to asymmetric strain.

Methodology in accordance with embodiments of the present includes forming fins in a substrate. A non-conformal sacrificial layer is formed over and between the fins. A first gap-fill dielectric is formed over the sacrificial layer and fins and the first gap-fill dielectric is recessed to expose an upper portion of the fins and sacrificial layer. The sacrificial layer is recessed to expose the fins. A second gap-fill dielectric is formed over the first gap-fill dielectric and over and between the fins; and the second gap-fill dielectric is recessed to expose the upper portion of the fins.

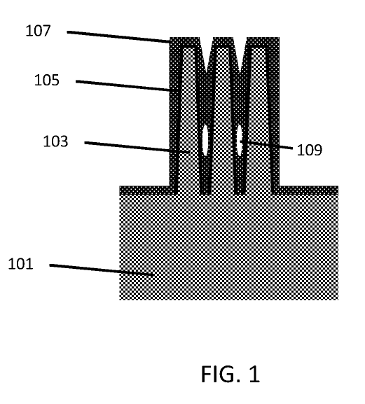

FIGS. 1 through 6 schematically illustrate cross-sectional views along the gate of a process flow for producing a FinFET structure without bent or collapsed fins, in accordance with exemplary embodiments. Adverting to FIG. 1, a plurality of silicon (Si) fins 103 are formed out of a Si substrate 101. An optional conformal liner 105 may be formed over the fins 103. The conformal liner 105 is only illustrated in FIG. 1 for illustrative convenience. The conformal liner 105 may be formed, e.g., of an oxide, and is formed, e.g., to a thickness of 5 to 10 nm over the fins 103 by a thermal oxidation process. As further shown in FIG. 1, a non-conformal CVD process is performed to deposit a non-conformal layer 107 over the fins 103. The non-conformal layer 107 may be formed, e.g., of silicon nitride (SiN) or other material that is selective to the etching process with respect to the first and second gap-fill layers. The non-conformal layer 107 is formed in such a manner that it pinches off the upper portions of the fins 103 and ties up the fins 103 to prevent deformation, i.e., bending or collapsing. The non-conformal layer 107 is deposited based on fin pitch to ensure merge between sidewalls of adjacent fins, e.g., to a thickness of 20 nm to 120 nm over the fins 103. The thickness of the non-conformal layer 107 is proportional to strength of the bond between the fins 103. As shown in FIG. 1, one or more voids 109 can form between the fins without any negative impact since the non-conformal layer 107 is a sacrificial layer and is removed during subsequent processing.

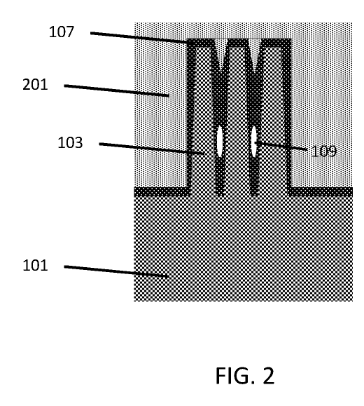

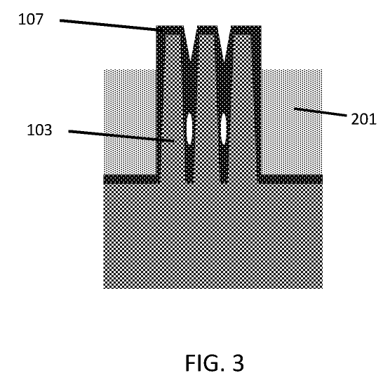

As shown in FIG. 2, a FCVD process is performed to deposit a first gap-fill dielectric layer 201 over the fins 103 and substrate 101. The formation of the first gap-fill dielectric layer 201 is a STI gap fill process. The fins 103 are not affected by a volumetric pull of the first gap-fill dielectric layer 201 since the fins are tied together by way of the non-conformal layer 107. The first gap-fill dielectric layer is subsequently annealed at a temperature of 200-1200° C. In FIG. 3, the first gap-fill dielectric layer 201 is recessed to expose an upper portion of the fins 103. The first gap-fill dielectric layer 201 is recessed by way of etching or CMP and RIE deglaze. The first gap-fill dielectric can include an oxide, nitride, carbon containing film, polysilazane, spin on dielectric and other dielectric materials. The non-conformal layer 107 remains following the recessing of the first gap-fill dielectric 201. The non-conformal layer 107 decouples the fins 103 from the FCVD process since it is deposited between the fins 103.

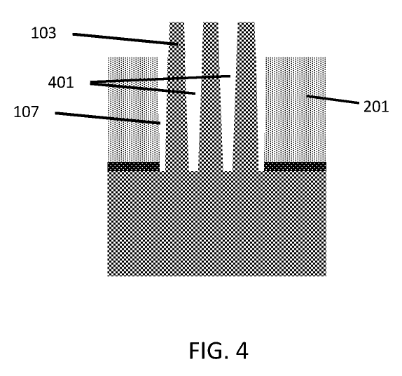

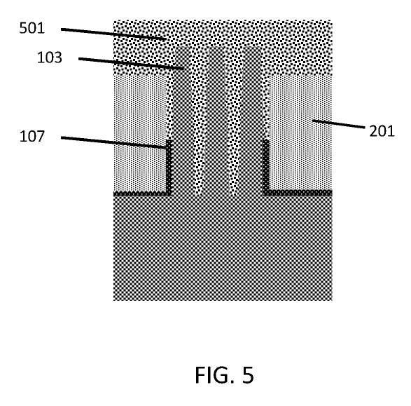

Adverting to FIG. 4, an etching step is performed to selectively remove the non-conformal layer 107 from the upper portions of the fins 103 and it is entirely removed from between the fins 103 in regions 401. A residual amount of the non-conformal layer 107 can remain along edges of the lower portion of the fins 103 (FIG. 5) or remain only at the bottom of the gap-fill oxide in the fin-gap areas (FIG. 4).

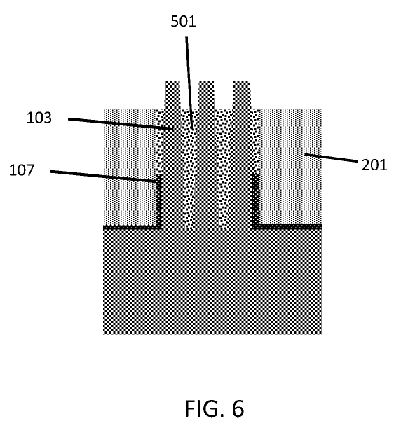

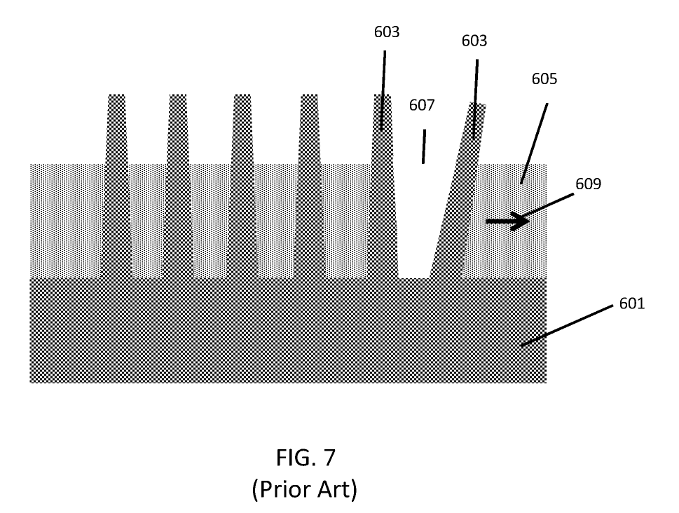

In FIG. 5, a second gap-fill dielectric layer 501 is deposited by FCVD and subsequently annealed. The second gap-fill dielectric can include an oxide, nitride, carbon containing film, polysilazane, spin on dielectric and other dielectric materials. This second STI gap fill partially fills the gaps formed by the removal of the non-conformal layer 107. As shown in FIG. 6, the second gap-fill dielectric layer 501 is recessed to expose an upper portion of the fins 103. Alternatively, the second gap-fill dielectric layer 501 may be formed by a controlled FCVD so that the gap fill is just below an upper portion of the fins 103. In this instance, no recessing of the second gap-fill dielectric layer 501 is required and it avoids fin tip bending.

Additional conventional FinFET processing steps (not shown for illustrative convenience) are then performed to form gates over and perpendicular to the fins 103.

The embodiments of the present disclosure can achieve several technical effects, including coalescing of fins prior to the STI gap-fill to improve structural integrity of the fins. Structural integrity of the fins independent of STI-fill film quality is improved, as well improvements with volumetric shrinkage, stress gradient, and pull during densification. The present disclosure decouples the STI gap-fill process for the wide fill area and the narrow fin area. A process window is also achieved to optimize STI gap-fill film quality. The present disclosure enjoys industrial applicability in any of various industrial applications, e.g., microprocessors, smart phones, mobile phones, cellular handsets, set-top boxes, DVD recorders and players, automotive navigation, printers and peripherals, networking and telecom equipment, gaming systems, and digital cameras. The present disclosure therefore enjoys industrial applicability in any of various types of FinFET devices, particularly in the 22 nm technology node and beyond.

In the preceding description, the present disclosure is described with reference to specifically exemplary embodiments thereof. It will, however, be evident that various modifications and changes may be made thereto without departing from the broader spirit and scope of the present disclosure, as set forth in the claims. The specification and drawings are, accordingly, to be regarded as illustrative and not as restrictive. It is understood that the present disclosure is capable of using various other combinations and embodiments and is capable of any changes or modifications within the scope of the inventive concept as expressed herein.

1. A method comprising:
forming fins in a substrate;
forming a non-conformal sacrificial layer over and between the fins so as to conjoin the fins or an array of the fins for structural integrity;
forming a first gap-fill dielectric over the sacrificial layer and fins;
recessing the first gap-fill dielectric to expose an upper portion of the fins and non-conformal sacrificial layer, wherein the non-conformal sacrificial layer remains over the upper portion of the fins following the recessing of the first gap-fill dielectric;
removing the non-conformal sacrificial layer in its entirety to expose the fins;
forming a second gap-fill dielectric over the first gap-fill dielectric and over and between the fins; and
recessing the second gap-fill dielectric to expose the upper portion of the fins.

2. The method according to claim 1, further comprising:
forming a conformal oxide liner over the fins prior to forming the non-conformal sacrificial layer.

3. The method according to claim 1, further comprising:
forming the first gap-fill dielectric over the sacrificial layer and fins with chemical vapor deposition (CVD), flowable CVD (FCVD), low-k FCVD SiOC, or spin on dielectric process; and
annealing the first gap-fill dielectric.

4. The method according to claim 1, comprising:
recessing the first gap-fill dielectric by etching; or
chemical mechanical polishing (CMP) and reactive ion etching (RIE) deglaze.

5. The method according to claim 1, comprising:
forming the non-conformal sacrificial layer of silicon nitride.

6. The method according to claim 1, comprising:
forming the second gap-fill dielectric with CVD, FCVD, low-k FCVD SiOC, or spin on dielectric process; and
annealing the second gap-fill dielectric.

7. The method according to claim 1, further comprising:
recessing the second gap-fill dielectric by etching; or
CMP and RIE deglaze.

8. The method according to claim 1, comprising:
etching the non-conformal sacrificial layer to expose the fins, wherein a portion of the sacrificial layer remains at the bottom of the fins adjacent the substrate.

9. The method according to claim 1, comprising:
forming the non-conformal sacrificial layer, wherein one or more voids is formed between the fins.

10. A method comprising:
forming fins in a substrate;
forming a non-conformal sacrificial layer over and between the fins;
forming a first gap-fill dielectric over the sacrificial layer and fins;
recessing the first gap-fill dielectric to expose an upper portion of the fins and non-conformal sacrificial layer, wherein the non-conformal sacrificial layer remains over the upper portion of the fins following the recessing of the first gap-fill dielectric;
removing the non-conformal sacrificial layer in its entirety to expose the fins; and
forming a second gap-fill dielectric over the first gap-fill dielectric leaving exposed an upper portion of the fins.

11. The method according to claim 10, further comprising:
forming a conformal oxide liner over the fins prior to forming the non-conformal sacrificial layer.

12. The method according to claim 10, further comprising:
forming the first gap-fill dielectric over the sacrificial layer and fins with chemical vapor deposition (CVD); and
annealing the first gap-fill dielectric.

13. The method according to claim 10, comprising:
recessing the first gap-fill dielectric by etching; or
chemical mechanical polishing (CMP) and reactive ion etching (RIE) deglaze.

14. The method according to claim 10, comprising:
forming the non-conformal sacrificial layer of silicon nitride or other material that is selective to the etching with respect to the first and second gap-fill dielectrics.

15. The method according to claim 10, comprising:
forming the second gap-fill dielectric with a controlled chemical vapor deposition (CVD), flowable CVD (FCVD), low-k FCVD SiOC, or spin on dielectric process; and
annealing the second gap-fill dielectric.

16. A device comprising:
fins formed in a substrate;
an etched sacrificial layer formed over the substrate and extending to a lower portion of the fins, wherein no etched sacrificial layer is present between adjacent fins;
a first gap-fill dielectric formed over the sacrificial layer extending up sides of the fins exposing an upper portion of the fins;
a second gap-fill dielectric formed over the first gap-fill dielectric and between the fins exposing the upper portion of the fins.

17. The device according to claim 16, wherein the etched sacrificial layer comprises silicon nitride or other material that is selective to the etching with respect to the first and second gap-fill dielectrics.

18. The device according to claim 16, wherein the first gap-fill dielectric comprises a shallow trench isolation (STI) gap fill material.

19. The device according to claim 16, further comprising a conformal oxide liner formed over the fins.

20. The device according to claim 16, further comprising a gate formed over the upper portion of the fins.
